(19) United States
(12) Patent Application Publication
(10) Pub. No.: US 2024/0420889 A1
(43) Pub. Date: Dec. 19, 2024

(54) CAPACITOR AND METHOD FOR MANUFACTURING CAPACITOR

(71) Applicant: Murata Manufacturing Co., Ltd., Nagaokakyo-shi (JP)

(72) Inventors: Sota YANAI, Nagaokako-shi (JP); Masaki NAGATA, Nagaokakyo-shi (JP); Yasuhiro SHIMIZU, Nagaokakyo-shi (JP)

(21) Appl. No.: 18/816,287

(22) Filed: Aug. 27, 2024

Related U.S. Application Data
(63) Continuation of application No. PCT/JP2023/006556, filed on Feb. 22, 2023.

(30) Foreign Application Priority Data
Apr. 26, 2022 (JP) 2022-072618

(51) Int. Cl. H01G 4/008

(52) U.S. Cl. CPC H01G 4/008; H01L 28/60

(57) ABSTRACT

A capacitor that includes: a substrate with conductivity; a plurality of fiber-shaped conductive members on the substrate and electrically connected to the substrate; a dielectric layer covering a surface of the plurality of fiber-shaped conductive members; and a conductor layer covering a surface of the dielectric layer, where the plurality of fiber-shaped conductive members includes a proximal half present proximally to the surface of the substrate and a distal half present distally to the surface of the substrate, and one of the proximal half and the distal half is higher in the number density of the plurality of fiber-shaped conductive members and larger in the thickness of the dielectric layer than the other of the proximal half and the distal half.

### CROSS REFERENCE TO RELATED APPLICATIONS

The present application is a continuation of International application No. PCT/JP2023/006556, filed Feb. 22, 2023, which claims priority to Japanese Patent Application No. 2022-072618, filed Apr. 26, 2022, the entire contents of each of which are incorporated herein by reference.

### TECHNICAL FIELD

The present disclosure relates to a capacitor and, more particularly, to a capacitor that has a conductor-dielectric-conductor structure. In addition, the present disclosure relates to a method for manufacturing such a capacitor.

### BACKGROUND ART

Conventionally, it is known that capacitors can be manufactured with the use of a fiber-shaped members. For example, Patent Document 1 describes a method of forming a capacitor that has a metal-insulator-metal (MIM) structure by forming nanofibers on a substrate (base surface) and sequentially forming, on the surface thereof, a lower plate (metal), an insulating layer, and an upper plate (metal).
Patent Document 1: Japanese Patent Application Laid-Open (Translation of PCT Application) No. 2010-506391

### Non-Patent Documents

Non-Patent Document 1: Mostafa Bedewy, et al., “Population Growth Dynamics of Carbon Nanotubes”, ACS Nano, 2011, Volume 5, Issue 11, pp. 8974-8989
Non-Patent Document 2: Nicholas T. Dee, et al., “Carbon-assisted catalyst pretreatment enables straight forward synthesis of high-density carbon nanotube forests”, Carbon, 2019, Volume 153, pp. 196-205

### SUMMARY OF THE INVENTION

When the fiber-shaped members have conductivity, a capacitor that has a conductor-dielectric-conductor structure can be formed by forming, on the surfaces of the fiber-shaped conductive members, a dielectric layer (directly or with a conductor layer interposed therebetween) and further forming a conductor layer.

As a plurality of fiber-shaped conductive members, for example, vertically aligned carbon nanotubes (hereinafter, referred to also as “VACNTs”) can be used. VACNTs can be obtained by high-density growth thereof on a synthetic substrate with a catalyst attached thereto. The thus obtained VACNTs, which are referred to also as a “CNT forest,” have been found to vary in the number density of CNTs depending on the distance from the surface of the synthetic substrate, while the CNTs all fail to extend uniformly in the vertical direction from the synthetic substrate. More specifically, Non-Patent Document 1 reports that the number density of CNTs is, with respect to positions from the tips (free ends) of VACNTs (CNT forest) to the surface of a synthetic substrate (the fixed ends of the VACNTs), low at tip parts of the VACNTs, and then rapidly increased to become a maximum at the position at a distance of about 75% of the whole length of the VACNT from the surface of the synthetic substrate, and decreased in a substantially linear manner from the position toward the surface of the synthetic substrate. In addition, Non-Patent Document 2 reports that the number density of CNTs is, with respect to positions from the tips (free ends) of VACNTs (CNT forest) to the surface of a synthetic substrate (the fixed ends of the VACNTs), high (maximum) at tip parts of the VACNTs, and decreased from the tip parts to the surface of the synthetic substrate.

In the case of manufacturing a capacitor that has a conductor-dielectric-conductor structure by forming a dielectric layer and a conductor layer on the surfaces of CNTs with the use of VACNTs that vary in number density depending on the distance from the surface of a synthetic substrate as described above, a large number of sites where CNTs are exposed from the dielectric layer can remain in a part where the number density of CNTs is high, which is considered as having a problem in that a large number of short circuit paths can be produced depending on the number of exposed sites when the capacitor is operated (described later in more detail with reference to FIG. 12). In order to reduce the number of exposed sites, simply increasing the thickness of the dielectric layer is conceivable. Simply increasing the thickness of the dielectric layer will, however, cause another problem of decreasing the capacitance density of the capacitor.

The foregoing problem is not limited to VACNTs, and can be caused in common in capacitors in which the number density of fiber-shaped conductive members in a plurality of fiber-shaped conductive members as a whole varies depending on the distance from the surface of a substrate.

An object of the present disclosure is to achieve a capacitor including a plurality of fiber-shaped conductive members used, in which the number of short circuit paths generated is reduced without substantially decreasing the capacitance density.

According to a gist of the present disclosure, provided is a capacitor including: a substrate with conductivity; a plurality of fiber-shaped conductive members on the substrate and electrically connected to the substrate; a dielectric layer covering the surface of the plurality of fiber-shaped conductive members; and a conductor layer covering a surface of the dielectric layer, where the plurality of fiber-shaped conductive members includes a proximal half present proximally to the surface of the substrate and a distal half present distally to the surface of the substrate, and one of the proximal half and the distal half is higher in the number density of the plurality of fiber-shaped conductive members and larger in the thickness of the dielectric layer than the other of the proximal half and the distal half.

According to another gist of the present disclosure, provided is a method for manufacturing a capacitor, including: (a) joining a first end of a plurality of fiber-shaped conductive members to a surface of a first substrate, wherein the plurality of fiber-shaped conductive members include a fixed end side half that is present proximally to the surface of the first substrate and a free end side half that is present distally to the surface of the first substrate, and the free end side half is higher in number density of the plurality of fiber-shaped conductive members than the fixed end side half; (b) covering a surface of the plurality of fiber-shaped conductive members with a first dielectric layer by a liquid phase film formation method or a sputtering method, wherein the free end side half is larger in thickness of the first dielectric layer than the fixed end side half; and (c) covering a surface of the first dielectric layer with a conductor layer.

According to the present disclosure, when the fiber-shaped conductive members is all considered divided into a proximal half that is present proximally and a distal half that is present distally with respect to the surface of the substrate in the capacitor including the plurality of fiber-shaped conductive members used, any one of the halves is higher in the number density of the fiber-shaped conductive members and larger in the thickness of the dielectric layer than the other. Thus, a capacitor can be achieved in which the number of short circuit paths generated is reduced without substantially decreasing the capacitance density.

### BRIEF EXPLANATION OF THE DRAWINGS

FIG. 1A shows a schematic sectional view of a capacitor according to Embodiment 1 of the present disclosure.

FIG. 1B is a view in which a dielectric layer and a conductor layer are omitted from FIG. 1A.

FIG. 2A shows a schematic sectional view of a capacitor according to Embodiment 2 of the present disclosure.

FIG. 2B is a view in which a dielectric layer and a conductor layer are omitted from FIG. 2A.

FIG. 3A shows a schematic sectional view of a capacitor according to Embodiment 3 of the present disclosure.

FIG. 3B is a view in which a dielectric layer and a conductor layer are omitted from FIG. 3A.

FIG. 4 shows a schematic sectional view of a capacitor according to a first modification example of Embodiment 2 of the present disclosure.

FIG. 5 shows a schematic sectional view of a capacitor according to a first modification example of Embodiment 1 of the present disclosure.

FIG. 6 shows a schematic sectional view of a capacitor according to a second modification example of Embodiment 2 of the present disclosure.

FIG. 7 shows a schematic sectional view of a capacitor according to a third modification example of Embodiment 2 of the present disclosure.

FIG. 8 shows a schematic sectional view of a capacitor according to a first modification example of Embodiment 3 of the present disclosure.

FIG. 9 shows an SEM image of a parallel direction section obtained by filling a sample fabricated according to Example 1 with a resin.

FIG. 10A shows an SEM image of a vertical direction section obtained by filling the sample fabricated according to Example 1 with the resin.

FIG. 10B is an enlarged view of a part A in FIG. 10A.

FIG. 11 shows an SEM image of a parallel direction section obtained by filling a sample fabricated according to Comparative Example 1 with a resin.

FIG. 12A shows a schematic cross-sectional view of a capacitor described in the present specification for the purpose of comparison to the present disclosure.

FIG. 12B is a view in which a dielectric layer and a conductor layer are omitted from FIG. 12A.

### DETAILED DESCRIPTION OF THE INVENTION

Capacitors according to three embodiments of the present disclosure will be described in detail below with reference to the drawings, but the present disclosure is not limited to these embodiments.

### Embodiment 1

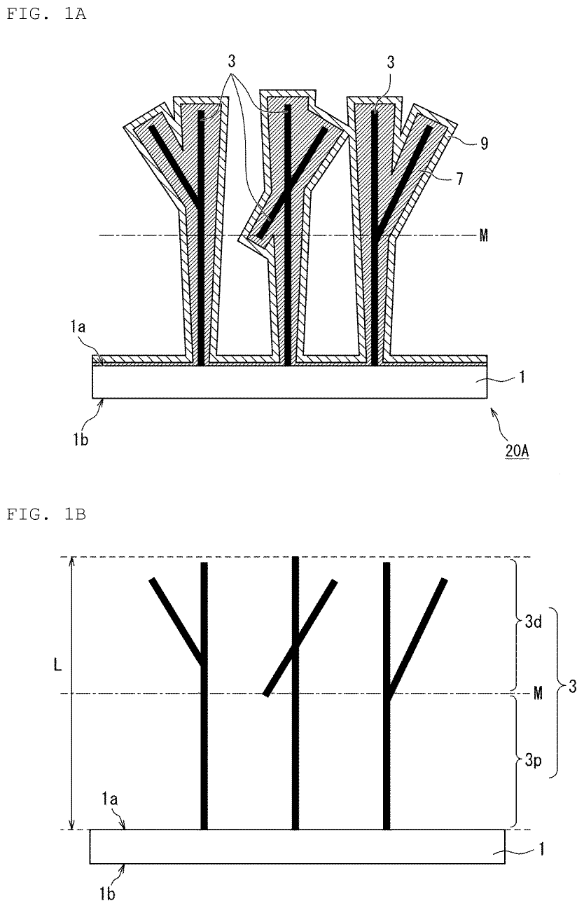

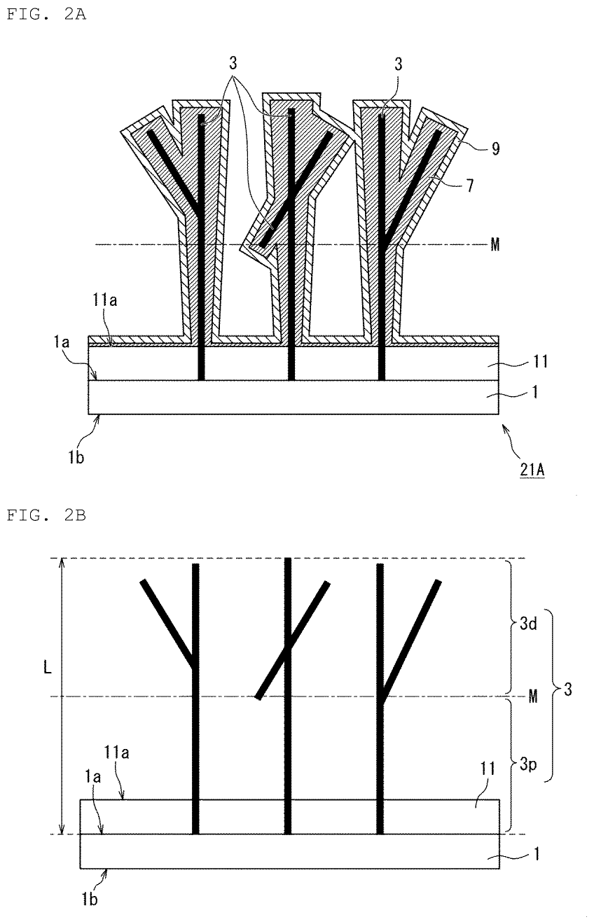

The present embodiment relates to an aspect in which the number density of fiber-shaped conductive members in a plurality of fiber-shaped conductive members is higher in a distal half than in a proximal half with respect to the surface of a substrate, and no adhesive layer is present (FIGS. 1A and 1B).

Referring to FIG. 1A, a capacitor 20A according to the present embodiment includes: a substrate 1 with conductivity; a plurality of fiber-shaped conductive members 3 on the substrate 1 and electrically connected to the substrate 1; a dielectric layer 7 that covers a surface of the plurality of fiber-shaped conductive members 3; and a conductor layer 9 that covers a surface of the dielectric layer 7.

The plurality of fiber-shaped conductive members 3 has conductivity, (which are typically conductors), which can be kept at the same potential or voltage as each other with the members electrically connected to the substrate 1. Accordingly, a conductor-dielectric-conductor structure is formed by the fiber-shaped conductive members 3, the dielectric layer 7, and the conductor layer 9. Such a conductor-dielectric-conductor structure can be understood as corresponding to a so-called MIM structure (metal-insulator-metal structure). The capacitor 20A that has such a structure can achieve a high capacitance density from the large specific surface area of the fiber-shaped conductive members 3.

FIG. 1B is a view in which the dielectric layer 7 and the conductor layer 9 are omitted for convenience for better understanding the capacitor 20A according to the present embodiment. When the plurality of fiber-shaped conductive members 3 is understood to be all virtually divided into two, it can be understood that the plurality of fiber-shaped conductive members 3 includes a proximal half 3p that is present proximally to a surface 1a of the substrate 1 and a distal half 3d that is present distally to the surface 1a of the substrate 1.

In FIGS. 1A and 1B, M means a virtual division line. M can be at a distance of 50% of the length L of the plurality of fiber-shaped conductive members 3 from the surface 1a of the substrate 1. It is to be noted that the length L of the plurality of fiber-shaped conductive members 3 is assumed to be the maximum length of the plurality of fiber-shaped conductive members 3 from the surface 1a of the substrate 1 in the present disclosure.

In the present disclosure, one of the proximal half 3p and the distal half 3d is higher than the other thereof in the number density (d) of the plurality of fiber-shaped conductive members 3 and larger than the other in the thickness (t) of the dielectric layer 7. In other words, the half (the one mentioned above) on the side where the number density of the plurality of fiber-shaped conductive members 3 is relatively high is larger than the half (the other mentioned above) on the side where the number density of the plurality of fiber-shaped conductive members 3 is relatively low in the thickness of the dielectric layer 7 covering the surface of the plurality of fiber-shaped conductive members 3.

More specifically, according to the present embodiment, the one mentioned above is the distal half 3d, and the other mentioned above is the proximal half 3p. More specifically, according to the present embodiment, the distal half 3d is higher in the number density (d) of the plurality of fiber-shaped conductive members 3 and larger in the thickness (t) of the dielectric layer 7 than the proximal half 3p. In other words, the distal half 3d where the number density of the plurality of fiber-shaped conductive members 3 is relatively high is larger than the proximal half 3p where the number density of the plurality of fiber-shaped conductive members 3 is relatively low in the thickness of the dielectric layer 7 covering the surface of the plurality of fiber-shaped conductive members 3.

With such a feature of the present disclosure, in the half on the side where the number density of the plurality of fiber-shaped conductive members 3 is relatively high (the distal half 3d according to the present embodiment), the thickness of the dielectric layer 7 can be relatively increased to effectively reduce, preferably substantially eliminate, the number of sites where the plurality of fiber-shaped conductive members 3 is exposed from the dielectric layer 7, and effectively reduce, preferably substantially eliminate, the number of short circuit paths produced when the capacitor 20A is operated. Further, in the half on the side where the number density of the plurality of fiber-shaped conductive members 3 is relatively low (the proximal half 3p according to the present embodiment), the thickness of the dielectric layer 7 can be relatively reduced to prevent the capacitance density of the capacitor 20A from being substantially decreased, and obtain a high capacitance density.

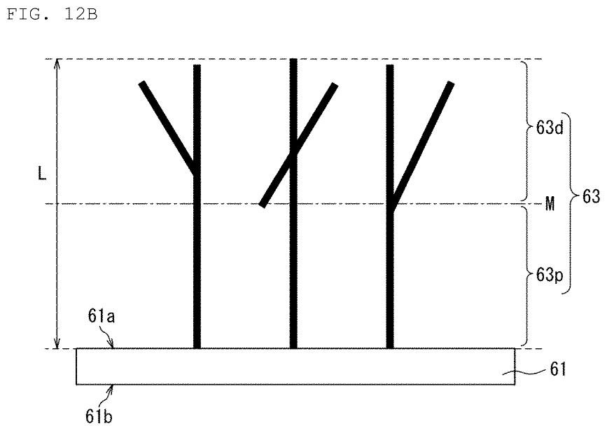

For comparison purposes, FIG. 12A shows a capacitor 60 in which a distal half 63d is higher than a proximal half 63p in the number density of a plurality of fiber-shaped conductive members 63, while both the distal half 63d and the proximal half 63p are uniform in the thickness of a dielectric layer 67 (FIG. 12B is a view corresponding to FIG. 1B). In the capacitor 60, a large number of sites (in FIG. 12A, representative one of the sites is surrounded by a dotted line) where the plurality of fiber-shaped conductive members 63 is exposed from the dielectric layer 67 may remain in the section where the number density of the plurality of fiber-shaped conductive members 63 is high (the distal half 63d in the illustrated aspect), and there is a problem that a large number of short circuit paths may be produced between the fiber-shaped conductive members 63 and the conductor layer 69 when the capacitor 60 is operated. Simply (in other words, uniformly) increasing the thickness of the dielectric layer 67 will lead to another problem of decreasing the capacitance density of the capacitor 60.

As understood from the foregoing, the capacitor according to the present disclosure can achieve a capacitor in which the number of short circuit paths generated is reduced, without substantially decreasing the capacitance.

In the present disclosure, the number density (also referred to as “number density”) d of the plurality of fiber-shaped conductive members is measured as follows. First, when the capacitor 20A has a space (in the capacitor 20A illustrated in FIGS. 1A and 1B, a space corresponding to the shape of the exposed surface of the conductor layer 9), the space is filled with any appropriate resin, and a section parallel to the surface 1a (“parallel direction section”) is exposed at a predetermined distance (or position) from the surface 1a of the substrate 1. Such a parallel direction section can be exposed by polishing. The parallel direction section thus exposed is observed with a scanning electron microscope (SEM), and the number of fiber-shaped conductive members per unit area is determined in one field of view of 3 μm×3 μm or more to obtain the number density in the field of view. Such an operation is repeated to obtain the number density in five or more fields of view, and the average value thereof is defined as the number density d of the plurality of fiber-shaped conductive members at the distance. The in-plane positions of the fields of view are not particularly limited, but are preferably selected so as to be substantially the same positions at respective distances. In other words, a region obtained by projecting each of fields of view selected in a parallel direction section at a certain distance with respect to the surface 1a of the substrate 1 is preferably substantially the same as a region obtained by projecting each of fields of view selected in a parallel direction section at another distance with respect to the surface 1a of the substrate 1.

The thickness t of the dielectric layer is measured as follows. After exposing a section parallel to the surface 1a at a predetermined distance from the surface 1a of the substrate 1 in the manner described above, next, a section perpendicular to the surface 1a of the substrate 1 (“vertical direction section”) is exposed. The thus exposed vertical direction section is observed with a scanning electron microscope (SEM), and in the SEM image, an isolated single fiber-shaped conductive member is selected from which a central part (ideally, a center line) in a longitudinal direction of the fiber-shaped conductive member is appearing and from which the dielectric layer covering the surface of the fiber-shaped conductive member and the conductor layer (according to the present embodiment, the boundary between the fiber-shaped conductive member and the dielectric layer and the boundary between the dielectric layer and the conductor layer) can be identified, an outer diameter D₁ in the vicinity of an end of the fiber-shaped conductive member on the side opposite to the substrate 1 and an outer diameter De of the dielectric layer covering the surface of the end are measured, the difference between these outer diameters is divided by 2, and thus as the value ((D₂−D₁)/2), the thickness of the dielectric layer covering the surface of the fiber-shaped conductive member can be determined. Such an operation is repeated to obtain the thickness of the dielectric layer for ten or more, preferably twenty or more fiber-shaped conductive members, and the average value thereof is defined as the thickness t of the dielectric layer at the distance. The outer diameter De of the dielectric layer is measured only for the dielectric layer covering the surface of the fiber-shaped conductive member. The vertical direction section may be one or more vertical direction sections obtained at any appropriate in-plane position.

The thickness t of the dielectric layer may be measured from a parallel direction section exposed at a predetermined distance from the surface 1a of the substrate 1. The parallel direction section is observed with an SEM, and in the SEM image, a single fiber-shaped conductive member is selected from which the dielectric layer covering the surface of the fiber-shaped conductive member and the conductor layer (according to the present embodiment, the boundary between the fiber-shaped conductive member and the dielectric layer and the boundary between the dielectric layer and the conductor layer) can be identified, an outer diameter Du of the fiber-shaped conductive member on the side opposite to the substrate 1 and an outer diameter D₂₁ of the dielectric layer covering the surface are measured, the difference between these outer diameters is divided by 2, and thus as the value ((D₂₁−D₁₁)/2), the thickness of the dielectric layer covering the surface of the fiber-shaped conductive member can be determined. Such an operation is repeated to obtain the thickness of the dielectric layer for ten or more, preferably twenty or more fiber-shaped conductive members, and the average value thereof is defined as the thickness t of the dielectric layer at the distance. The outer diameter D₂₁ of the dielectric layer is measured only for the dielectric layer covering the surface of the fiber-shaped conductive member.

The number density (d) of the plurality of fiber-shaped conductive members 3 and the thickness (t) of the dielectric layer 7 in the distal half 3d may be any number density and thickness inside the distal half 3d. In one representative example, a number density (d₇₅) and a thickness (t₇₅) at a distance of 75% of the length L of the plurality of fiber-shaped conductive members 3 from the surface 1a of the substrate 1 can be applied. The number density d₇₅ and the thickness t₇₅ can be obtained by exposing a parallel direction section or a vertical direction section at a distance of 75% of the length L from the surface 1a of the substrate 1. It is to be noted that in the present disclosure, the number density and thickness measured by setting the exposed position at the distance of 75% are permitted to be treated as the number density d₇₅ and the thickness t₇₅, if the actual measurement position is slightly deviated (for example, within the range of 75%+5%). In another representative example, a number density (d₉₀) and a thickness (t₉₀) at a distance of 90% of the length L of the plurality of fiber-shaped conductive members 3 from the surface 1a of the substrate 1 can be applied. The number density d₉₀ and the thickness too can be obtained by exposing a parallel direction section or a vertical direction section at a distance of 90% of the length L from the surface 1a of the substrate 1. It is to be noted that in the present disclosure, the number density and thickness measured by setting the exposed position at the distance of 90% are permitted to be treated as the number density d₉₀ and the thickness too, if the actual measurement position is slightly deviated (for example, within the range of 90%+5%).

The number density (d) of the plurality of fiber-shaped conductive members 3 and the thickness (t) of the dielectric layer 7 in the proximal half 3p may be any number density and thickness inside the proximal half 3p. In one representative example, a number density (d₂₅) and a thickness (t₂₅) at a distance of 25% of the length L of the plurality of fiber-shaped conductive members 3 from the surface 1a of the substrate 1 can be applied. The number density d₂₅ and the thickness t₂₅ can be obtained by exposing a parallel direction section or a vertical direction section at a distance of 25% of the length L from the surface 1a of the substrate 1. It is to be noted that in the present disclosure, the number density and thickness measured by setting the exposed position at the distance of 25% are permitted to be treated as the number density d₂₅ and the thickness t₂₅, if the actual measurement position is slightly deviated (for example, within the range of 25%±5%). In another representative example, a number density (d₁₀) and a thickness (t₁₀) at a distance of 10% of the length L of the plurality of fiber-shaped conductive members 3 from the surface 1a of the substrate 1 can be applied. The number density d₁₀ and the thickness t₁₀ can be obtained by exposing a parallel direction section or a vertical direction section at a distance of 10% of the length L from the surface 1a of the substrate 1. It is to be noted that in the present disclosure, the number density and thickness measured by setting the exposed position at the distance of 10% are permitted to be treated as the number density d₁₀ and the thickness t₁₀, if the actual measurement position is slightly deviated (for example, within the range of 10%±5%).

Accordingly, in one representative example, the capacitor 20A according to the present embodiment can satisfy d₇₅>d₂₅ and t₇₅>t₂₅. Accordingly, in another representative example, the capacitor 20A according to the present embodiment can satisfy d₉₀>d₁₀ and t₉₀>t₁₀.

The number density d of the plurality of fiber-shaped conductive members 3 can differ (vary) depending on the relative distance from the surface 1a of the substrate 1 (based on the length L of the plurality of fiber-shaped conductive members 3). Although the present embodiment is not to be considered limited, the number density d of the plurality of fiber-shaped conductive members 3 may be low at 100%, then rapidly increased to reach a maximum at about 75%, and decreased (for example, in a substantially linear manner) from the maximum to 0% with respect to the relative distance of 100% to 0% from the surface 1a of the substrate 1 in one representative example. For example, d₇₅>d₉₀>d₂₅>d₁₀ may be met. In another representative example, the number density d of the plurality of fiber-shaped conductive members 3 may be high (can be a maximum) at 100 to 90% (a c of the plurality of fiber-shaped conductive members 3 or the vicinity thereof), and decreased (for example, in a substantially linear manner) therefrom to 10 to 0% (the surface 1a of the substrate 1 or the vicinity thereof) with respect to the relative distance of 100% to 0% from the surface 1a of the substrate 1. For example, d₉₀>d₇₅>d₂₅>d₁₀ may be met.

The thickness t of the dielectric layer 7 can differ (vary) depending on the relative distance from the surface 1a of the substrate 1 (based on the length L of the plurality of fiber-shaped conductive members 3). The thickness t of the dielectric layer 7 can be considered to desirably differ depending on the number density d of the plurality of fiber-shaped conductive members 3, which is not essential to the present disclosure, and the thickness t can differ (vary) independently from the number density d. Although the present embodiment is not to be considered limited, the thickness t of the dielectric layer 7 may be decreased (for example, in a substantially linear manner) from 100% to 0% with respect to the relative distance from the surface 1a of the substrate 1 from 100% to 0%. For example, t₉₀>t₇₅>t₂₅>t₁₀ may be met.

Although the present embodiment is not to be considered limited, the half (the one mentioned above, which is the distal half 3d according to the present embodiment) on the side where the number density of the plurality of fiber-shaped conductive members 3 is relatively high may have more surface defects at the plurality of fiber-shaped conductive members 3 than the half (the other mentioned above, which is the proximal half 3p according to the present embodiment) on the side where the number density of the plurality of fiber-shaped conductive members 3 is relatively low. With more surface defects, the dielectric layer 7 can be formed to be thicker. Accordingly, a thicker dielectric layer can be formed in the half on the side where the number density of the plurality of fiber-shaped conductive members 3 is relatively high. This respect will be described in detail in the description of the method for manufacturing the capacitor 20A.

In the present disclosure, the fiber-shaped conductive member 3 (each of the plurality of fiber-shaped conductive members 3) is not particularly limited as long as the longitudinal direction dimension (length) thereof is (preferably remarkably) larger than the maximum sectional dimension perpendicular to the longitudinal direction, that is, the fiber-shaped conductive member 3 generally has the form of an elongated thread.

The length of the fiber-shaped conductive member 3 is preferably larger because the capacitance density per area can be increased. The length of the fiber-shaped conductive member 3 can be, for example, several μm or more, 20 μm or more, 50 μm or more, 100 μm or more, 500 μm or more, 750 μm or more, 1000 μm or more, or 2000 μm or more. The upper limit of the length of the fiber-shaped conductive member 3 can be appropriately selected, and the length of the fiber-shaped conductive member 3 can be, for example, 10 mm or less, 5 mm or less, or 3 mm or less.

The maximum sectional dimension of the fiber-shaped conductive member 3 can be, for example, 0.1 nm or more, 1 nm or more, or 10 nm or more. The maximum sectional dimension of the fiber-shaped conductive member 3 can be, for example, 1 nm or more, or 10 nm or more. The maximum sectional dimension of the fiber-shaped conductive member 3 can be less than 1000 nm, 800 nm or less, or 600 nm or less.

The distance between the adjacent fiber-shaped conductive members 3 is preferably smaller because the capacitance density per area can be increased. The distance between the adjacent fiber-shaped conductive members 3 can be, for example, 10 nm to 1 μm. The present disclosure is, however, not limited thereto, and the adjacent fiber-shaped conductive members 3 may have partial contact with each other.

The fiber-shaped conductive members 3 are preferably conductive nanofibers (with a maximum sectional dimension of nanoscale (1 nm to 1000 nm)). The conductive nanofibers may be, for example, conductive nanotubes (hollow, preferably cylindrical) or conductive nanorods (solid, preferably columnar). Nanorods with electrical conductivity (including semiconductivity) are also referred to as nanowires.

The conductive nanofibers that can be used according to the present disclosure are not particularly limited, and examples thereof include carbon nanofibers. The conductive nanotubes that can be used according to the present disclosure are not particularly limited, and examples thereof include metal-based nanotubes, organic conductive nanotubes, and inorganic conductive nanotubes. Typically, the conductive nanotubes can be carbon nanotubes or titania carbon nanotubes. The conductive nanorods (nanowires) that can be used according to the present disclosure are not particularly limited, and examples thereof include silicon nanowires and silver nanowires.

Preferably, the fiber-shaped conductive members 3 are carbon nanotubes. Carbon nanotubes have electrical conductivity and thermal conductivity. Carbon nanotubes are high in strength and flexibility, and are easily kept vertically aligned.

The chirality of the carbon nanotube is not particularly limited, and may have either a semiconductor type or a metal type, or a mixture thereof may be used. From the viewpoint of reducing the resistance value, the ratio of the metal type is preferably high.

The number of layers of the carbon nanotube is not particularly limited, and the carbon nanotube may be either a SWCNT (single-walled carbon nanotube) that has one layer or a MWCNT (multi-walled carbon nanotube) that has two or more layers.

The plurality of fiber-shaped conductive members 3 may be vertically aligned carbon nanotubes (VACNTs). The VACNTs have the advantages of having a large specific surface area and allowing the production by growth in a vertically aligned state on a synthetic substrate as described later. Although referred to as VACNTs, in practice, the CNTs all fail to extend uniformly in the vertical direction from the synthetic substrate, and the number density of CNTs can differ depending on the distance from the surface of the synthetic substrate. This respect will be described in detail in the description of the method for manufacturing the capacitor 20A.

The substrate 1 has two main surfaces 1a (front surface) and 1b (back surface) that have each other, and may have the form of, for example, a plate (substrate), foil, film, block, or the like.

The material constituting the substrate 1 can be selected appropriately, as long as the material has electrical conductivity, and can be electrically connected to the plurality of fiber-shaped conductive members 3. The material can be, for example, a semiconductor material such as silicon, a conductive material such as a metal (copper, aluminum, or nickel), or an insulating (or relatively poorly conductive) material such as a ceramic (silicon oxide) or a resin. The substrate 1 may be composed of one type of material, composed of a mixture of two or more kinds of materials, or may be a composite composed of two or more kinds of materials. The material constituting the substrate 1 is preferably a metal because the metal is easily used as a contact with the outside, is capable of reducing the resistance value, and can withstand high temperatures.

The thickness of the substrate 1 is not particularly limited, and can vary depending on the application of the capacitor 20A. The substrate 1 may be provided with an electrode for contacting the outside and a wiring for ensuring electrical conduction.

In the capacitor 20A according to the present embodiment, as illustrated in FIG. 1A, the plurality of fiber-shaped conductive members 3 may be directly joined to the substrate 1 (more specifically, the fiber-shaped conductive members 3 are joined to the substrate 1 in direct contact with each other, still more specifically, the fiber-shaped conductive members 3 and the substrate 1 are directly synthesized as described later) without an adhesive layer. Because of the absence of any adhesive layer, the height of the capacitor 20A can be reduced by the thickness of the adhesive layer.

As illustrated in FIG. 1A, the dielectric layer 7 may generally cover the surface 1a (excluding the regions joined to the plurality of fiber-shaped conductive members 3) of the substrate 1, in addition to the surface of the plurality of fiber-shaped conductive members 3 (excluding the regions directly joined to the substrate 1).

The dielectric material constituting the dielectric layer 7 can be selected appropriately, and examples thereof include a silicon dioxide, an aluminum oxide, a silicon nitride, a tantalum oxide, a hafnium oxide, a barium titanate, and a lead zirconate titanate. These materials may be used alone, or two or more thereof may be used (for example, as a laminate).

The thickness t of the dielectric layer 7 is preferably 5 nm or more, more preferably 10 nm or more. The thickness of the dielectric layer is 5 nm or more, thereby making it possible to enhance the insulation property and allowing leakage current to be reduced. In addition, the thickness t of the dielectric layer 7 can be, for example, 1 μm or less, and is preferably 100 nm or less, more preferably 50 nm or less. The thickness t of the dielectric layer 7 is 1 μm or less, thereby allowing a higher electrostatic capacitance to be obtained.

The conductive material constituting the conductor layer 9 is not particularly limited, and may be, for example, a metal, a conductive polymer (which is a polymer material with conductivity and/or imparted with conductivity, and is also referred to as an organic conductive material), or the like. These materials may be used alone, or two or more thereof may be used. Examples of the metal include silver, gold, copper, platinum, aluminum, and an alloy containing at least two thereof. Examples of the conductive polymer include a PEDOT (polyethylene dioxythiophene), a PPy (polypyrrole), and a PANI (polyaniline), and these polymers may be appropriately doped with a dopant such as an organic sulfonic acid-based compound, for example, a polyvinyl sulfonic acid, a polystyrene sulfonic acid, a polyallyl sulfonic acid, a polyacrylic sulfonic acid, a polymethacrylic sulfonic acid, a poly-2-acrylamide-2-methylpropane sulfonic acid, or a polyisoprene sulfonic acid. The conductor layer 9 may be a laminate of multiple layers that differ in conductive material.

The thickness of the conductor layer 9 can be, for example, 3 nm or more, preferably 10 nm or more. The thickness of the conductor layer 9 is 3 nm or more, thereby allowing the resistance value of the conductor layer 9 itself to be reduced. In addition, the thickness of the conductor layer 9 can be, for example, 500 nm or less, particularly 100 nm or less. According to the present embodiment, the conductor layer 9 can be, as illustrated, provided with gaps (or a trench structure) corresponding to the spaces between the plurality of fiber-shaped conductive members 3. The thickness of the conductor layer 9 may be, for example, thicker, and for example, the gaps (trench structure) may be eliminated.

The capacitor 20A according to the present embodiment can be obtained, for example, by a manufacturing method including: (a) preparing a plurality of fiber-shaped conductive members 3 disposed on a first substrate and directly joined, at one end of each of the members, (more specifically, fixed by direct synthesis as described later) to the first substrate, where the plurality of fiber-shaped conductive members 3 is composed of a fixed end side half that is present proximally to a surface of the first substrate and a free end side half that is distally to the surface of the first substrate, and the free end side half is higher in the number density (d) of the plurality of fiber-shaped conductive members 3 than the fixed end side half; (b) forming the dielectric layer 7 that covers the surface of the plurality of fiber-shaped conductive members 3 by a liquid phase film formation method or a sputtering method, where the free end side half is larger in the thickness (t) of the dielectric layer 7 than the fixed end side half; and (c) forming a conductor layer 9 that covers the surface of the dielectric layer 7.

In the present embodiment, the first substrate is the same as the substrate 1 in the capacitor 20A. In addition, in the present embodiment, the fixed end side half and free end side half of the plurality of fiber-shaped conductive members 3 respectively correspond to the proximal half 3p and distal half 3d in the capacitor 20A.

Hereinafter, steps (a) to (c) will be described in more detail. Although an exemplary case where the fiber-shaped conductive members 3 are VACNTs will be described below, in the present embodiment, the fiber-shaped conductive members 3 are not limited to VACNTs, and the capacitor 20A may be manufactured with the use of any appropriate method depending on the fiber-shaped conductive members 3 to be used. In addition, unless otherwise specified, the above description in the present embodiment can also be applied to the following manufacturing method.

### Step (a)

First, the plurality of fiber-shaped conductive members 3 disposed on the first substrate and directly joined, at one end of each of the members, to the first substrate is prepared.

The step (a) can be performed by applying a catalyst onto the first substrate and causing the plurality of fiber-shaped conductive members 3 to grow from the first substrate (in other words, directly synthesizing the plurality of fiber-shaped conductive members 3 on the first substrate). More details are as follows.

The first substrate may be a synthetic substrate for causing VACNTs to grow as the fiber-shaped conductive members 3. In general, the material of the synthetic substrate is not particularly limited, and for example, silicon oxide, silicon, gallium arsenide, aluminum, or SUS can be used. In the present embodiment, the substrate 1 with conductivity is used as the first substrate (synthetic substrate).

First, a catalyst is attached onto the first substrate (synthetic substrate). As the catalyst, iron, nickel, platinum, cobalt, an alloy containing these metals, or the like is used. Methods such as chemical vapor deposition (CVD), sputtering, physical vapor deposition (PVD), atomic layer deposition (ALD) can be used for the method for attaching the catalyst to the synthetic substrate, and in some cases, such a technique may be combined with a technique such as lithography or etching.

Then, VACNTs are allowed to grow (directly synthesized) on the synthetic substrate with the catalyst attached thereto. The method for the VACNT growth is not particularly limited, and CVD, plasma-enhanced CVD, or the like can be used under heating as necessary. The gas used is not particularly limited, and for example, at least one selected from the group consisting of carbon monoxide, methane, ethylene, and acetylene, or a mixture of at least one thereof and hydrogen and/or ammonia can be used. If desired, moisture may be present in the ambient atmosphere for VACNT growth. Thus, VACNTs grow with the catalyst as a nucleus on the synthetic substrate. The end of the VACNT on the side of the synthetic substrate with the catalyst attached is a fixed end that is fixed to the synthetic substrate (typically with the catalyst interposed therebetween), and the opposite end of the VACNT is a free end that is a growth point. The length and diameter of the VACNT may vary depending on changes in parameters such as a gas concentration, a gas flow rate, and a temperature. More specifically, the length and diameter of the VACNT can be adjusted by appropriately selecting these parameters.

As a result, the VACNTs (CNT forest) are prepared on the synthetic substrate. Strictly speaking, the length of each of CNTs in the obtained VACNTs can vary (for example, cause in-plane variations) on the free end side due to a difference in growth rate or the like, and the maximum length thereof is defined as the length L of the VACNT. The number density (d) of CNTs in the obtained VACNTs will vary with respect to the relative distance from the surface of the synthetic substrate (based on the length L of the VACNT) from 100% to 0%. In one representative example, the number density (d) can be small at the relative distance of 100%, then rapidly increased to a maximum at about 75%, and then decreased therefrom to 0% (for example, in a substantially linear manner) (Non-Patent Document 1). In another representative example, the number density d can be large (can be a maximum) at the relative distance 100 to 90%, and decreased therefrom to 10 to 0% (for example, in a substantially linear manner) (Non-Patent Document 2).

When the VACNTs are allowed to grow on the synthesis substrate with the catalyst attached thereto, the growth of some CNTs is stopped due to the catalyst deactivated in the process of the VACNT synthesis. The CNTs whose growth is stopped are entangled with the subsequently growing CNTs and then pulled, thereby making the fixed ends away from the synthetic substrate and pulled up toward the tips of the VACNTs. As a result, in the obtained VACNTs, the number density (d) of CNTs is considered as varying depending on the distance (relative distance) from the surface of the synthetic substrate as described above.

The VACNTs (the plurality of fiber-shaped conductive members 3) obtained as described above are disposed on the first substrate (synthetic substrate) and directly joined, at one end of each of the VACANT, to the first substrate (as understood from the description mentioned above, however, some CNTs of the VACNTs may be indirectly joined to the first substrate). When such VACNTs are all understood to be virtually divided into two, it can be understood that the VACNTs are composed of a fixed end side half that is present proximally to the surface of the first substrate and a free end side half that is present distally to the surface of the first substrate. Further, the number density (d) of CNTs in such VACNTs is higher in the free end side half than in the fixed end side half.

### Step (b)

Next, the dielectric layer 7 covering the surface of the VACNTs (the plurality of fiber-shaped conductive members 3) is formed by a liquid phase film formation method or a sputtering method.

The liquid phase film formation method can be, for example, a sol-gel method, plating, or the like. When the dielectric layer 7 is made of a metal oxide, a method of plating in combination with a surface oxidation treatment may be used.

The conditions for implementing the liquid phase film formation method are appropriately selected or set, thereby allowing the thickness (t) of the dielectric layer 7 formed to vary depending on the distance from the surface of the first substrate, and allowing the thickness (t) of the dielectric layer 7 to be made larger in the free end side half than in the fixed end side half. The liquid phase film formation method is easily adjusted in the production of a substance to serve as a nucleus of a reaction for forming a film and the degree of ingress of the substance between CNTs (for example, the substance can be adsorbed more on the surface of the CNTs on the free end side, and the amount of the substance entering can be reduced toward the fixed end).

Although the present embodiment is not to be considered limited, for example, the prepared composition of the liquid for use in the liquid phase film formation method, the solvent (for example, water, ethanol, isopropanol) for use in the preparation, the film formation time, the stirring speed, the temperature, and the like are appropriately selected or set.

The method for forming the dielectric layer 7 is, however, not necessarily limited to the liquid phase film formation method as long as the thickness (t) of the dielectric layer 7 can be made larger in the free end side half than in the fixed end side half. For example, a sputtering method, which is one of vapor phase film formation methods, may be applied. More specifically, in order to change the thickness of the dielectric layer 7 in the sputtering method, what is required is appropriately selecting a material (raw material) and appropriately selecting or setting conditions for implementation of a positional relationship (distance, angle) between a substrate for the material substrate and the material to be deposited.

In addition, although not essential to the present embodiment, a treatment for introducing surface defects into the VACNTs may be performed after the step (a) and before the step (b). The treatment for introducing surface defects may be an acid treatment, a heat treatment, a UV treatment, or the like.

The conditions for performing the treatment for introducing surface defects are appropriately selected or set, thereby allowing the number of surface defects introduced to vary depending on the distance from the surface of the first substrate, and allowing the number of surface defects to be made larger in the free end side half than in the fixed end side half.

With more surface defects, the dielectric layer 7 can be formed to be thicker. Accordingly, a thicker dielectric layer can be formed in the free end side half where the number density of VACNTs is relatively high.

The surface defects of the CNTs can be evaluated, based on the G/D ratio obtained with the use of Raman spectroscopy. The G/D ratio is the ratio of a G band (peak around 1590 cm⁻¹, derived from the in-plane vibration of a six-membered ring that is common to carbon-based substances) and a D band (peak around 1350 cm⁻¹, derived from defects), and is used as an index for the quantity of defects in CNTs. The reduced G/D ratio means more surface defects. In addition, the surface defects may be surface functional groups such as a hydroxy group or a carboxyl group. Functional groups that are present on the surface of the CNTs can be quantitatively evaluated by X-ray photoelectron spectroscopy (XPS) or the like.

### Step (c)

Thereafter, the conductor layer 9 covering the surface of the dielectric layer 7 is formed.

The film formation method for the conductor layer 9 is not particularly limited, and a liquid phase film formation method, a vapor phase film formation method, and a combination thereof may be used. The liquid phase film forming method can be, for example, a sol-gel method, plating, or the like. The vapor phase film formation method can be ALD, sputtering, CVD, or the like.

For example, the conductor layer 9 can be formed by a liquid phase film formation method with the use of a conductive polymer. More specifically, the conductor layer 9 can be formed by applying/supplying (for example, performing application, immersion, or the like), to a predetermined surface/part, a liquid composition that has a conductive polymer dissolved or dispersed in an organic solvent. The conductive polymer is easily allowed to penetrate into spaces formed between the plurality of fiber-shaped conductive members 3 covered with the dielectric layer 7, and the conductor layer 9 can be formed appropriately also in deep parts (for example, bottom parts) of the spaces.

As described above, referring to FIG. 1A again, the capacitor 20A including the plurality of fiber-shaped conductive members 3 (VACNTs) disposed on the first substrate with conductivity (the same as the substrate 1 in the present embodiment) and electrically connected to the first substrate, the dielectric layer 7, and the conductor layer 9 can be manufactured.

Further, In the present embodiment, the substrate 1 included in the capacitor 20A is the same as the first substrate used for fabricating the capacitor 20A, and is a synthetic substrate. The fact that the substrate 1 is a synthetic substrate can be determined by detecting the catalyst. When the substrate 1 included in the capacitor is analyzed to detect the catalyst on the surface of the substrate 1, the substrate 1 may be considered as a synthetic substrate.

### Embodiment 2

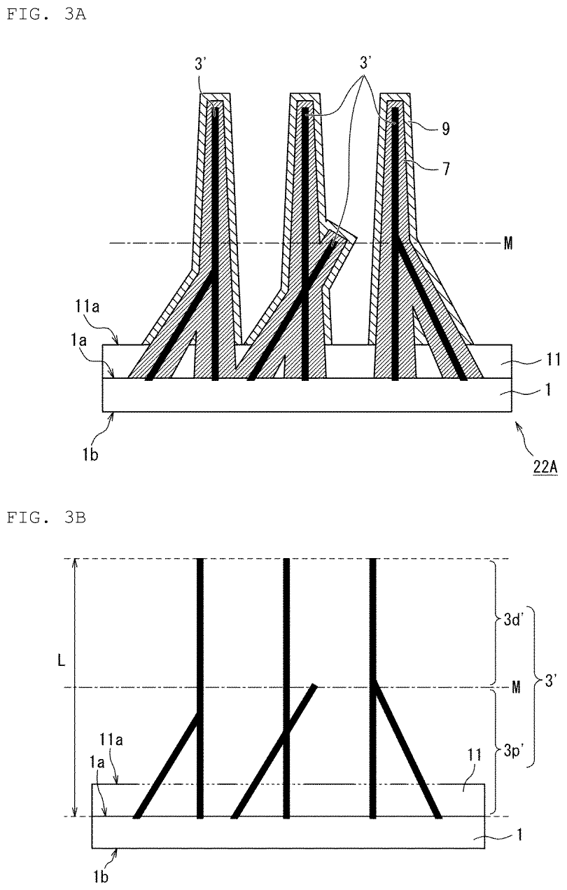

The present embodiment relates to an aspect in which the number density of fiber-shaped conductive members in a plurality of fiber-shaped conductive members is higher in a distal half than in a proximal half with respect to the surface of a substrate, and an adhesive layer is present (FIGS. 2A and 2B). In the present embodiment, unless otherwise specified, the description in Embodiment 1 can also be applied to the present embodiment (the same applies to the following embodiments and modification examples).

Referring to FIG. 2A, a capacitor 21A according to the present embodiment has a plurality of fiber-shaped conductive members 3 joined to a substrate 1 with an adhesive layer 11.

According to the present embodiment, as illustrated in FIG. 2A, the dielectric layer 7 may generally cover a surface 11a (excluding the regions joined to the plurality of fiber-shaped conductive members 3) of the adhesive layer 11, in addition to the surface of the plurality of fiber-shaped conductive members 3 (excluding the regions directly joined to the substrate 1 and the regions buried in the adhesive layer 11).

According to the present embodiment, the adhesive layer 11 may have conductivity, or have no conductivity. When the adhesive layer 11 has conductivity, the plurality of fiber-shaped conductive members 3 can be reliably kept at the same potential or voltage via the adhesive layer 11, and can be reliably electrically connected to the substrate 1.

The capacitor 21A according to the present embodiment may be manufactured by any appropriate method. Examples thereof include, but are not limited to, the following first and second manufacturing examples.

According to the first manufacturing example, in the method for manufacturing the capacitor 20A described above in Embodiment 1, a curable (or fluid, the same shall apply hereinafter) material may be supplied onto the surface 1a (excluding the regions joined to the plurality of fiber-shaped conductive members 3) of the substrate 1 and then subjected to curing (or allowed to lose the fluidity, the same shall apply hereinafter) to form the adhesive layer 11 after the step (a) and before the step (b). Further, in the case of performing the treatment for introducing surface defects into the plurality of fiber-shaped conductive members 3 (VACNTs), the treatment may be performed either before or after the formation of the adhesive layer 11. Thereafter, the capacitor 21A can be obtained in the same manner as in Embodiment 1.

In the first manufacturing example, the substrate 1 included in the capacitor 21A is the same as the first substrate used for fabricating the capacitor 21A, and is a synthetic substrate. As described in Embodiment 1, the fact that the substrate 1 is a synthetic substrate can be determined by detecting the catalyst. When the substrate 1 included in the capacitor is analyzed to detect the catalyst on the surface of the substrate 1, the substrate 1 may be considered as a synthetic substrate.

The adhesive layer 11 that can be used in the first manufacturing example may be, for example, a cured product (or non-fluidized product) of any appropriate curable (or fluid) material (for example, a so-called adhesive). The curable (or fluid) material may be a curing material, is, for example, a material that is made curable by heat, light, radiation, moisture, or the like, and is preferably a thermosetting material. Alternatively, the curable (or fluid) material may be a thermoplastic material, and the thermoplastic material is made plasticized/fluid in advance by heating, supplied (for example, poured) onto the surface 1a of the substrate 1 (excluding the regions joined to the plurality of fiber-shaped conductive members 3), and then allowed to lose the fluidity by heat dissipation to form the adhesive layer 11. The curable material can be a known adhesive or adhesive paste, and may optionally include a conductive filler.

Examples of the conductive curable material include a conductive filler dispersed in any curable resin/polymer, and a conductive and curable resin/polymer. Examples of the former include a material that has a metal filler such as gold, silver, nickel, copper, tin, or palladium, or a carbon filler dispersed in a resin such as an epoxy resin, a polyimide resin, a silicone resin, or a polyurethane resin. Examples of the latter include polypyrrole, polypyrrole derivatives, polyaniline, polyaniline derivatives, polythiophene, and polythiophene derivatives.

The curable material may have the form of a paste, a sheet, a gel, or a liquid. For easily pouring the curing material into the gaps between the plurality of fiber-shaped conductive members 3, preferred is a liquid or gel-like curing material, or a thermosetting material or a thermoplastic material that can become liquid or gel-like with the viscosity decreased once at the time of heating.

According to the second manufacturing example, in the method for manufacturing the capacitor 20A described above in Embodiment 1, after the step (a) and before the step (b), the plurality of fiber-shaped conductive members 3 on the first substrate may be transferred onto any appropriate support substrate, the first substrate may be removed, the plurality of fiber-shaped conductive members 3 on the support substrate may be transferred to the separately prepared substrate 1 with the adhesive layer 11 on the surface 1a, and the support substrate may be removed. Further, in the case of performing the treatment for introducing surface defects into the plurality of fiber-shaped conductive members 3 (VACNTs), the treatment can be performed at any appropriate timing. Thereafter, the capacitor 21A can be obtained in the same manner as in Embodiment 1.

In the second manufacturing example, the substrate 1 included in the capacitor 21A is different from the first substrate used for fabricating the capacitor 21A. Thus, in the second manufacturing example, there is no need for the first substrate to have conductivity, and any appropriate substrate can be used. In the second manufacturing example, the substrate 1 included in the capacitor 21A is not a first substrate, and thus, is not a synthetic substrate. The fact that the substrate 1 is not a synthetic substrate can be determined by detecting no catalyst. When the substrate 1 included in the capacitor is analyzed to detect no catalyst on the surface of the substrate 1, the substrate 1 may be considered as not a synthetic substrate.

In the second manufacturing example, the plurality of fiber-shaped conductive members 3 may be bonded (for example, chemically) on the surface of the adhesive layer 11, or may be bonded (for example, chemically and/or physically and mechanically) with the ends thereof inserted inside the adhesive layer 11. In the latter case, the plurality of fiber-shaped conductive members 3 can be more firmly bonded to the adhesive layer 11 by the anchor effect, and the peeling resistance can be enhanced.

The adhesive layer 11 that can be used in the second manufacturing example may be, for example, a cured product (or non-fluidized product) of any appropriate curable (or fluid) material (for example, a so-called adhesive). The curable (or fluid) material can be the same as that described above. In the case of using the curable (or fluid) material, the ends of the plurality of fiber-shaped conductive members 3 are brought into contact with or inserted into the curable (or fluid) material, then, and the curing material is subjected to curing (or allowed to lose the fluidity), and thus, the plurality of fiber-shaped conductive members 3 can be fixed to the adhesive layer 11.

Alternatively, the adhesive layer 11 that can be used in the second manufacturing example may be made of, for example, any appropriate metal material. The metal material may be titanium, gold, copper, aluminum, or the like. In the case of using the metal material, the plurality of fiber-shaped conductive members 3 can be fixed to the adhesive layer 11 by performing a high-speed heat treatment with the ends of the plurality of fiber-shaped conductive members 3 in contact with the metal material (for example, titanium, gold, or the like) or by mechanically press-fitting (piercing) the ends into the metal material (for example, copper, aluminum, or the like).

According to the present embodiment, in addition to the advantageous effects described above in Embodiment 1, the plurality of fiber-shaped conductive members 3 can be firmly bonded to the substrate 1 by the adhesive layer 11.

### Embodiment 3

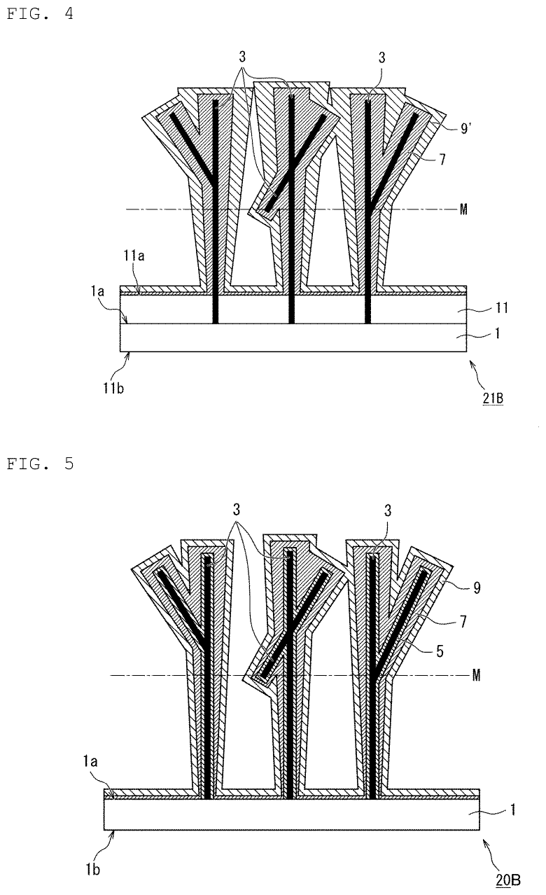

The present embodiment relates to a case in which the number density of fiber-shaped conductive members in a plurality of fiber-shaped conductive members is higher in the proximal half than in the distal half with respect to the surface of a substrate, and an adhesive layer has no conductivity (FIGS. 3A and 3B). (further, in a similar aspect, a case in which the adhesive layer has conductivity will be described later as a first modification example of Embodiment 3 with reference to FIG. 8) According to the present embodiment, the same members as those in Embodiment 1 to 2 are denoted by the same reference numerals, and unless otherwise specified, the descriptions in Embodiment 1 to 2 can also apply to the present embodiment.

Referring to FIG. 3A, a capacitor 22A according to the present embodiment includes: a substrate 1 with conductivity; a plurality of fiber-shaped conductive members 3′ disposed on the substrate 1 and electrically connected to the substrate 1; a dielectric layer 7 that covers the surface of the plurality of fiber-shaped conductive members 3′; and a conductor layer 9 that covers the surface of the dielectric layer 7.

Schematically, in the capacitor 22A according to the present embodiment, the plurality of fiber-shaped conductive members 3′ is understood as being vertically inverted from the plurality of fiber-shaped conductive members 3 described above (see FIGS. 1A, 1B, 2A, and 2B).

In the present disclosure, one of a proximal half 3p′ and a distal half 3d′ is higher than the other in the number density (d) of the plurality of fiber-shaped conductive members 3′ and larger in the thickness (t) of the dielectric layer 7.

More specifically, according to the present embodiment, the one mentioned above is the proximal half 3p′, and the other mentioned above is the distal half 3d′. More specifically, according to the present embodiment, the proximal half 3p′ is higher in the number density (d) of the plurality of fiber-shaped conductive members 3′ and larger in the thickness (t) of the dielectric layer 7 than the distal half 3d′. In other words, the proximal half 3p′ where the number density of the plurality of fiber-shaped conductive members 3′ is relatively high is larger than the distal half 3d′ where the number density of the plurality of fiber-shaped conductive members 3′ is relatively low in the thickness of the dielectric layer 7 covering the surface of the plurality of fiber-shaped conductive members 3′.

Accordingly, in one representative example, the capacitor 22A according to the present embodiment can satisfy d₇₅<d₂₅ and t₇₅<t₂₅. Accordingly, in another representative example, the capacitor 22A according to the present embodiment can satisfy d₉₀<d₁₀ and t₉₀<t₁₀.

Although the present embodiment is not to be considered limited, the number density d of the plurality of fiber-shaped conductive members 3′ may be low at 0%, then rapidly increased to reach a maximum at about 25%, and decreased (for example, in a substantially linear manner) from the maximum to 100% with respect to the relative distance of 0% to 100% from the surface 1a of the substrate 1 in one representative example. For example, d₂₅>d₅>d₇₅>d₉₀ may be met. In another representative example, the number density d of the plurality of fiber-shaped conductive members 3′ may be high (can be a maximum) at 0 to 10%, and decreased (for example, in a substantially linear manner) therefrom to 90 to 100% with respect to the relative distance of 0% to 100% from the surface 1a of the substrate 1. For example, d₁₀>d₂₅>d₇₅>d₉₀ may be met.

Although the present embodiment is not to be considered limited, the thickness t of the dielectric layer 7 may be decreased (for example, in a substantially linear manner) from 0% to 100% with respect to the relative distance from the surface 1a of the substrate 1 from 0% to 100%. For example, t₁₀>t₂₅>t₇₅>t₉₀ may be met.

Although the present embodiment is not to be considered limited, the half (the one mentioned above, which is the proximal half 3p′ according to the present embodiment) on the side where the number density of the plurality of fiber-shaped conductive members 3′ is relatively high may have more surface defects at the plurality of fiber-shaped conductive members 3′ than the half (the other mentioned above, which is the distal half 3d′ according to the present embodiment) on the side where the number density of the plurality of fiber-shaped conductive members 3′ is relatively low.

Referring to FIG. 3A, a capacitor 22A according to the present embodiment has the plurality of fiber-shaped conductive members 3′ joined to the substrate 1 with an adhesive layer 11. According to the present embodiment, the adhesive layer 11 has no conductivity (more specifically, has a dielectric/insulating property).

As illustrated in FIG. 3A, the dielectric layer 7 covers the surface (excluding the regions directly joined to the substrate 1) of the plurality of fiber-shaped conductive members 3′. The conductor layer 9 covers the surface of the dielectric layer 7 (excluding the regions buried in the adhesive layer 11). When the adhesive layer 11 has no conductivity as in the present embodiment, the conductor layer 9 may fail to generally cover the surface 11a (excluding the region joined to the plurality of fiber-shaped conductive members 3′ and the dielectric layer 7) of the adhesive layer 11 (FIG. 3A), and may generally cover the surface (not illustrated). It is to be noted that when the conductor layer 9 fails to generally cover the surface 11a of the adhesive layer 11, it is preferable, but limited thereto, to make the same modification as a second modification example of Embodiment 2 described later (more specifically, for the capacitor 22A to further include a conductor part 13 in contact with the conductor layer 9).

The capacitor 22A according to the present embodiment can be obtained, for example, by a manufacturing method including: (a) preparing a plurality of fiber-shaped conductive members 3′ disposed on a first substrate and directly joined, at one end of each of the members, to the first substrate, where the plurality of fiber-shaped conductive members 3′ is composed of a fixed end side half that is present proximally to a surface of the first substrate and a free end side half that is distally to the surface of the first substrate, and the free end side half is higher in the number density (d) of the plurality of fiber-shaped conductive members 3′ than the fixed end side half; (b) forming the dielectric layer 7 that covers the surface of the plurality of fiber-shaped conductive members 3′ by a liquid phase film formation method or a sputtering method, where the free end side half is larger in the thickness (t) of the dielectric layer 7 than the fixed end side half; (d) exposing, from the dielectric layer 7, the plurality of fiber-shaped conductive members 3′ at free end parts opposite to the first substrate, bringing the free end parts (parts exposed from the dielectric layer 7) of the plurality of fiber-shaped conductive members 3′ into contact with the adhesive layer 11 located on a second substrate with conductivity to transfer the plurality of fiber-shaped conductive members 3′ to the second substrate, removing the first substrate from the plurality of fiber-shaped conductive members 3′, and then covering, with a dielectric layer, parts (fixed end parts before the transfer) of the plurality of fiber-shaped conductive members 3′, exposed by removing the first substrate; and (c) forming a conductor layer 9 that covers the surface of the dielectric layer 7.

In the present embodiment, the first substrate is different from the substrate 1 in the capacitor 22A. In addition, in the present embodiment, the fixed end side half and free end side half of the plurality of fiber-shaped conductive members 3′ respectively correspond to the distal half 3d′ and proximal half 3p′ in the capacitor 22A.

Hereinafter, steps (a) to (b), (d), and (c) will be described in more detail. Although an exemplary case where the fiber-shaped conductive members 3′ are VACNTs will be described below, in the present embodiment, the fiber-shaped conductive members 3′ are not limited to VACNTs, and the capacitor 22A may be manufactured with the use of any appropriate method depending on the fiber-shaped conductive members 3′ to be used.

### Steps (a) to (b)

The steps (a) to (b) can be similar to steps (a) to (b) described above in Embodiment 1. In the present embodiment, however, the first substrate (synthetic substrate) may have conductivity, or have no conductivity.

### Step (d)

After the step (b), from the free end parts of the VACNTs (plurality of fiber-shaped conductive members 3′) opposite to the first substrate, the dielectric layer 7 is removed to expose the VACNTs from the dielectric layer 7. For the removal of the dielectric layer 7, any appropriate method may be used, and the dielectric layer 7 can be removed from the free end parts of the VACNTs by, for example, cutting the tips, dissolving the dielectric layer with a chemical solution, or the like.

Separately, the adhesive layer 11 without conductivity is formed on the surface of the second substrate (transfer substrate) with conductivity.

In the present embodiment, the substrate 1 with conductivity is used as the second substrate (transfer substrate).

In the present embodiment, the adhesive layer 11 can be made of any appropriate material as long as the material has no conductivity. For example, as described above in the second manufacturing example of Embodiment 2, the adhesive layer may be made of the cured product (or non-fluidized product) of any appropriate curable (or fluid) material without conductivity. Unless otherwise specified, the same description as in the second manufacturing example of Embodiment 2 can be applied to the present embodiment.

Thereafter, the VACNTs and the dielectric layer 7 covering the VACNTs are inserted into the adhesive layer 11 such that the free end parts (parts exposed from the dielectric layer 7) of the VACNTs (the plurality of fiber-shaped conductive members 3′) have direct contact with the second substrate, thereby transferring the VACNTs to the second substrate, and the first substrate is removed from the VACNTs.

As described above, in the present embodiment, the adhesive layer 11 has no conductivity. When the adhesive layer 11 has no conductivity, the VACNTs (plurality of fiber-shaped conductive members 3′) can be allowed to penetrate through the adhesive layer 11 and then pushed into the second substrate (substrate 1) to be electrically connected to the second substrate (substrate 1).

Before the transfer to the second substrate (remaining directly synthesized on the first substrate), the length (the position of the free end) of each of CNTs can vary due to a difference in growth rate or the like on the free end side of the VACNTs (the plurality of fiber-shaped conductive members 3′). In contrast, on the fixed end side of the VACNTs, the length of (the position of the fixed end) of each of the CNTs hardly varies, and may be considered uniform. According to the present embodiment, the free end side of the VACNTs (plurality of fiber-shaped conductive members 3′) can be inserted into the adhesive layer 11 by transfer, and thus, the variations can be absorbed, and the lengths of the VACNTs (plurality of fiber-shaped conductive members 3′) from the surface of the second substrate (substrate 1) can be made more uniform (for example, as compared with the case of Embodiment 1). The thickness of the adhesive layer 11 is preferably larger than the length of the part where the length of each of the CNTs varies.

After the transfer, a dielectric is added to the parts (fixed end parts before the transfer) of the VACNTs (plurality of fiber-shaped conductive members 3′), exposed by removing the first substrate, thereby covering the exposed parts of the VACNTs with the dielectric layer 7. The addition of the dielectric may be performed to the extent that the exposed parts of the VACNTs are sufficiently covered with the use of the same method as the formation of the dielectric layer in the step (b).

### Step (c)

The step (c) can be similar to step (c) described above in Embodiment 1.

As described above, referring to FIG. 3A again, the capacitor 22A including the plurality of fiber-shaped conductive members 3′ (VACNTs) disposed on the second substrate with conductivity (the same as the substrate 1 in the present embodiment) and electrically connected to the second substrate, the dielectric layer 7, and the conductor layer 9 can be manufactured.

According to the present embodiment, in addition to the advantageous effects described above in Embodiment 1 to 2, the half on the side where the number density of the plurality of fiber-shaped conductive members 3′ is relatively high (the proximal half 3p′ according to the present embodiment) is transferred to the substrate 1 with the adhesive layer 11 interposed therebetween, and thus, the plurality of fiber-shaped conductive members 3′ can be more firmly joined to the substrate 1.

In addition, according to the present embodiment, the fixed end side half of the plurality of fiber-shaped conductive members 3′ serves as the distal half 3d′, and thus, variations (for example, in-plane variations) in length L of the plurality of fiber-shaped conductive members 3′ can be reduced, and high dimensional uniformity can be obtained.

### First Modification Example of Embodiment 2

The present modification example relates to an example in which the thickness of the conductor layer is modified to be different in Embodiment 2 (FIG. 4).

In a capacitor 21B according to the present embodiment, a conductor layer 9′ includes a conductive polymer. The conductive polymer can be the same as that described above in Embodiment 1.

Furthermore, referring to FIG. 4, in the capacitor 21B according to the present embodiment, the thickness t′ of the conductor layer 9′ can differ (vary) depending on the relative distance from the surface 1a of the substrate 1 (based on the length L of the plurality of fiber-shaped conductive members 3). Although the present embodiment is not to be considered limited, the thickness t′ of the conductor layer 9′ may be decreased (for example, in a substantially linear manner) from 100% to 0% with respect to the relative distance from the surface 1a of the substrate 1 from 100% to 0%. For example, t′₉₀>t′₇₅>t′₂₅>t′₁₀ may be met. It is to be noted that the thickness t′ of the conductor layer 9′ can be measured, based on the same idea as the measurement of the thickness t of the dielectric layer 7.

Such a conductor layer 9′ can be formed by a liquid phase film formation method. The liquid phase film formation method can be, for example, a sol-gel method, plating, or the like. More specifically, the conductor layer 9 can be formed by applying/supplying (for example, performing application, immersion, or the like), to a predetermined surface/part, a liquid composition that has a conductive polymer dissolved or dispersed in an organic solvent.

The conditions for implementing the liquid phase film formation method are appropriately selected or set, thereby allowing the thickness t′ of the conductor layer 9′ formed to vary depending on the distance from the surface of the first substrate, and allowing the thickness t′ of the conductor layer 9′ to be made larger in the free end side half than in the fixed end side half. When the first substrate is the same as the substrate 1 in the capacitor 21B, the thickness t′ of the conductor layer 9′ can be made larger in the distal half than in the proximal half with respect to the surface 1a of the substrate 1 as illustrated in FIG. 4.

Although the present embodiment is not to be considered limited, for example, the prepared composition of the liquid for use in the liquid phase film formation method, the solvent (for example, water, ethanol, isopropanol) for use in the preparation, the film formation time, the stirring speed, the temperature, and the like are appropriately selected or set.

According to the present embodiment, the thickness t′ of the conductor layer 9′ is larger in the distal half than in the proximal half with respect to the surface 1a of the substrate 1, and external contact is thus easily made with the use of a thicker part of the conductor layer 9′.

### First Modification Example of Embodiment 1

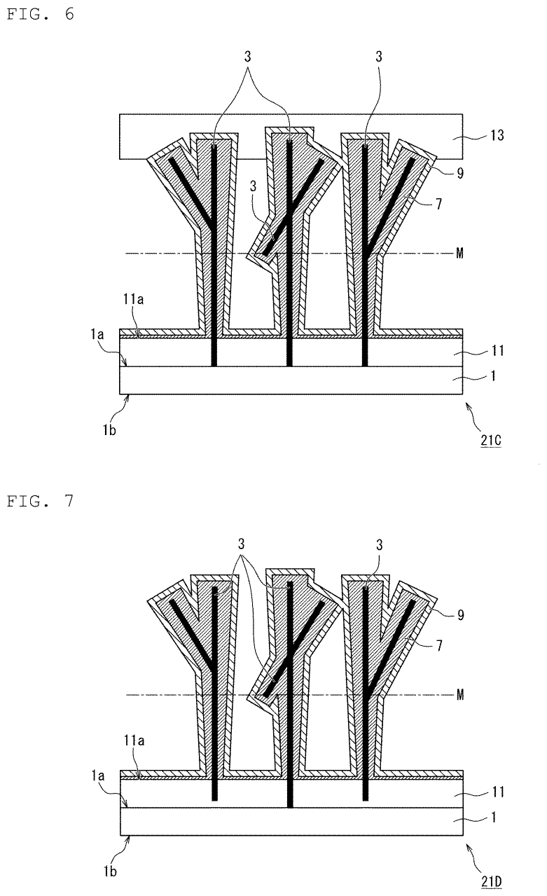

The present modification example relates to an example in which a modification is made to add another conductor layer in Embodiment 1 (FIG. 5).

Referring to FIG. 5, a capacitor 20B according to the present modification further includes another conductor layer 5 between a plurality of fiber-shaped conductive members 3 and a dielectric layer 7. Such a conductor layer 5 can be understood as an underlying conductor layer for the dielectric layer 7.

As illustrated in FIG. 5, the conductor layer 5 may cover the surface 1a (excluding the regions joined to the plurality of fiber-shaped conductive members 3) of the substrate 1, in addition to the surface of the plurality of fiber-shaped conductive members 3.

The same description as that of the conductor layer 9 can be applied to the material, structure, formation method, and the like of the conductor layer 5.

According to the present modification example, the equivalent series resistance (ESR) of the capacitor 20B can be reduced by providing another conductor layer 5 between the plurality of fiber-shaped conductive members 3 and the dielectric layer 7.

### Second Modification Example of Embodiment 2

The present modification example relates to an example in which a modification is made by adding a conductor part in contact with the conductor layer in Embodiment 2 (FIG. 6).

As illustrated in FIG. 6, a capacitor 21C according to the present modification further includes a conductor part 13 in contact with a conductor layer 9.

The conductor part 13 in contact with the conductor layer 9 is electrically connected to the conductor layer 9. The conductor part 13 is not in contact with the dielectric layer 7, the fiber-shaped conductive members 3, the substrate 1, or the adhesive layer 11. The conductor part 13 is not particularly limited as long as the conductor part 13 has conductivity, and for example, the conductor part 13 can be formed by applying/supplying a conductive paste to a predetermined surface/part. The conductor part 13 may be, for example, a layer formed in contact with the conductor layer 9 above the plurality of fiber-shaped conductive members 3 covered with the dielectric layer 7 and the conductor layer 9, or may be intended to fill (for example, some of) the spaces formed between the plurality of fiber-shaped conductive members 3 covered with the dielectric layer 7 and the conductor layer 9. It is to be noted that because the conductive paste generally has a relatively high viscosity, the conductive paste is, also in the latter case, considered as hardly penetrating into the spaces and failing to reach deep parts (for example, bottom parts) of the spaces.

Optionally, the capacitor 21C may further include another substrate (not illustrated) in contact with the conductor part 13. If present, another substrate can cover the conductor part 13 on the side opposite to the conductor layer 9, and may be, for example, a resin layer or the like. The resin layer can serve as an exterior resin that seals the element structure (conductor-dielectric-conductor structure) of the capacitor 21C. The resin layer can be formed from any appropriate resin material. The resin material is not particularly limited, and known resin materials for sealing can be used, which can be, for example, fine particles such as silica dispersed in a thermosetting epoxy resin. Another substrate is, however, not limited to the resin layer, and may be made of another material.

According to the present modification example, the conductor part 13 facilitates external contact. If present, another substrate may be provided with an electrode for contacting the outside or a wiring for ensuring electrical conduction.

### Third Modification Example of Embodiment 2

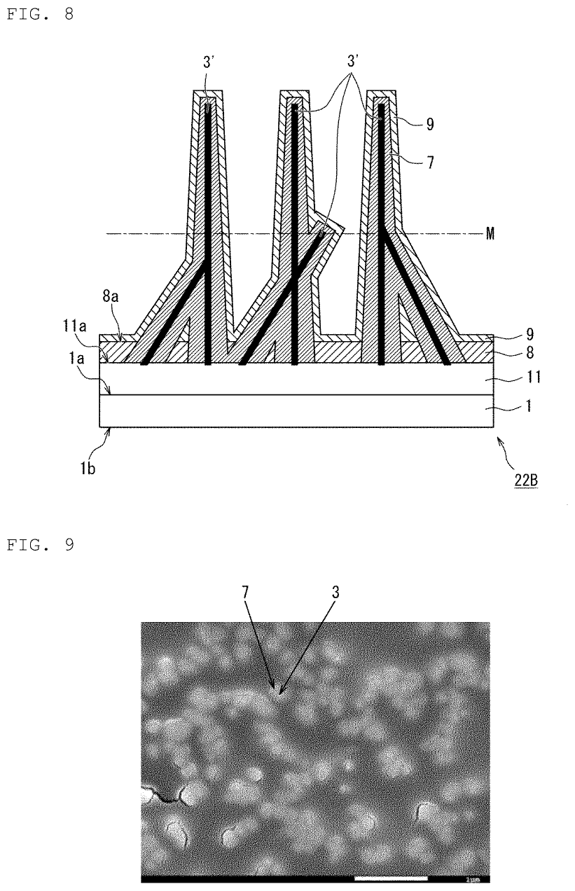

The present modification example relates to an example in which the electrical connection between the plurality of fiber-shaped conductive members and the substrate is modified in the case where the adhesive layer has conductivity in Embodiment 2 (FIG. 7).

In a capacitor 21D according to the present modification example, an adhesive layer 11 has conductivity. In the capacitor 21D, as illustrated in FIG. 7, as long as a plurality of fiber-shaped conductive members 3 has contact with the conductive adhesive layer 11, some or all of the plurality of fiber-shaped conductive members 3 may fail to have direct contact with (be directly joined to) the substrate 1.

The capacitor 21D can be fabricated by using an adhesive layer with conductivity as the adhesive layer 11 in Embodiment 2, and further modifying the adhesive layer as follows, for example. In the case of the first manufacturing example, some or all of the plurality of fiber-shaped conductive members 3 may be separated from the substrate 1 for some reason, and in the case of the second manufacturing example, some or all of the plurality of fiber-shaped conductive members 3 may fail to reach the substrate 1 at the time of transfer to the substrate 1 with the adhesive layer 11 on the surface 1a.

According to the present modification example, because the adhesive layer 11 has conductivity, the plurality of fiber-shaped conductive members 3 can be, regardless of whether or not the fiber-shaped conductive members 3 have contact with the substrate 1, reliably kept at the same potential or voltage via the adhesive layer 11, and reliably electrically connected to the substrate 1, thereby allowing an appropriate function as a capacitor.

In addition, according to the present modification example, the adhesive layer 11 has conductivity, thereby allowing the equivalent series resistance (ESR) of the capacitor 21D to be reduced.

### First Modification Example of Embodiment 3

The present modification example relates to an example in which Embodiment 3 is modified so as to be capable of functioning appropriately as a capacitor in the case where the adhesive layer has conductivity (FIG. 8).

In a capacitor 22B according to the present modification example, an adhesive layer 11 has conductivity. In the capacitor 22B, as illustrated in FIG. 8, as long as a plurality of fiber-shaped conductive members 3′ has contact with the conductive adhesive layer 11, some or all of the plurality of fiber-shaped conductive members 3′ may fail to have direct contact with (be directly joined to) the substrate 1. Alternatively, also in the present modification example, as in Embodiment 3, the plurality of fiber-shaped conductive members 3′ may have direct contact with (directly joined to) the substrate 1 (for example, also in the present modification example, as in FIGS. 3A and 3B, the plurality of fiber-shaped conductive members 3′ and a dielectric layer 7 may be inserted into the adhesive layer 11 to penetrate through the adhesive layer 11).

On a surface 11a of the conductive adhesive layer 11 (excluding the regions bonded to the plurality of fiber-shaped conductive members 3′ and the dielectric layer 7), a dielectric layer 8 is present. The dielectric layer 8 may be optionally integrated with the dielectric layer 7. The dielectric layer 8 is not particularly limited as long as the dielectric layer 8 has a dielectric/insulating property, and can be made of, for example, the same material as the dielectric layer 7. The conductor layer 9 may have contact with the dielectric layer 8, but has no contact with the fiber-shaped conductive member 3′, the adhesive layer 11, or the substrate 1. The conductor layer 9 may fail to generally cover a surface 8a (excluding the region joined to the plurality of fiber-shaped conductive members 3′ and the dielectric layer 7) of the dielectric layer 8 (not illustrated), and may generally cover the surface (FIG. 8).

Such a capacitor 22B can be fabricated further, for example, in the following manner, with the use of, as the adhesive layer 11, an adhesive layer with conductivity instead of an adhesive layer without conductivity in Embodiment 3. Steps (a) to (b) can be the same as the description in Embodiment 3. A step (d) can be the same as the description in Embodiment 3, except that VACNTs and the dielectric layer 7 covering the VACNTs are appropriately disposed on the adhesive layer 11 or appropriately inserted into the adhesive layer 11 such that free end parts (parts exposed from the dielectric layer 7) of the VACNTs (the plurality of fiber-shaped conductive members 3′) have direct contact with the adhesive layer 11, thereby transferring the VACNTs to a second substrate, and after the transfer, a dielectric is added to the parts (fixed end parts before the transfer) of the VACNTs (the plurality of fiber-shaped conductive members 3′), exposed by removing the first substrate, and the exposed parts of the surface 11a of the adhesive layer 11 to cover the exposed parts of the VACNTs with the dielectric layer 7 and form the dielectric layer 8. A step (c) can be the same as the description in Embodiment 3.

In the present embodiment, the adhesive layer 11 can be made of any appropriate material as long as the material has conductivity. For example, as described above in the second manufacturing example of Embodiment 2, the adhesive layer may be made of the cured product (or non-fluidized product) of any appropriate curable (or fluid) material with conductivity, or may be made of any appropriate metal. Unless otherwise specified, the same description as in the second manufacturing example of Embodiment 2 can be applied to the present embodiment.

According to the present modification example, because the adhesive layer 11 has conductivity, the plurality of fiber-shaped conductive members 3′ can be, regardless of whether or not the fiber-shaped conductive members 3′ have contact with the substrate 1, reliably kept at the same potential or voltage via the adhesive layer 11, and reliably electrically connected to the substrate 1, thereby allowing an appropriate function as a capacitor.

In addition, according to the present modification example, the adhesive layer 11 has conductivity, thereby allowing the equivalent series resistance (ESR) of the capacitor 22B to be reduced.

While the three embodiments and various modification examples of the present disclosure have been described in detail above, the present disclosure is not limited thereto. For example, any two or more of the respective features of the embodiments and modification examples describe above may be combined.

### EXAMPLES

### Example 1

Example 1 relates to the capacitor according to Embodiment 1, but the formation of the conductor layer was omitted.

A catalyst was applied onto the surface of a Si substrate, and VACNTs were allowed to grow. The length of the VACNTs (the maximum length of CNTs) L was about 100 μm, and the outer diameter of the CNTs was about 20 nm. For the VACNTs on the Si substrate, a dielectric layer of SiO₂ was formed by a sol-gel method. More specifically, the VACNTs on the Si substrate were immersed in a raw material mixture solution obtained by mixing a tetraethoxysilane (TEOS) as a raw material and an ethanol as a solvent, and maintained at 25° C. for 15 hours while stirring to form a dielectric layer of SiO₂ on the surfaces of the VACNTs and Si substrate. Thus, the structure of the VACNTs and dielectric (SiO₂) layer formed on the Si substrate was obtained as a sample according to Example 1.

For the sample according to Example 1, spaces on the dielectric layer, following the shapes of VACNTs, were filled with a resin, and a section parallel to the surface of the Si substrate was then exposed by polishing at a predetermined distance (relative distance of 90%) from the surface of the Si substrate (the surface with the grown VACNTs). The parallel direction section thus exposed was observed with an SEM, and the number (CNT number density d) of fiber-shaped conductive members per unit area was determined in a field of view of 3 μm×3 μm.

Furthermore, a section perpendicular to the surface of the Si substrate was exposed by FIB. The vertical direction section thus exposed was observed with an SEM. The thickness t of the dielectric layer was determined from an SEM image at a predetermined relative distance (relative distance of 90%). More specifically, a CNT was selected, which was entangled with no CNT and could be recognized as an isolated single CNT, from which a central part in a longitudinal direction of the CNT was appearing and from which the dielectric layer (SiO₂) covering the surface of the CNT could be clearly identified (the boundary between the CNT and the dielectric layer and the boundary between the dielectric layer and the resin layer could be identified), an outer diameter D₁ of the CNT and an outer diameter De of the dielectric layer covering the surface of the CNT were measured, the difference between these outer diameters was divided by 2, and thus as the value ((D₂−D₁)/2), the thickness of the dielectric layer was be determined. Such an operation was repeated to measure the thickness of the dielectric layer for ten or more CNTs, and the average value thereof was defined as the thickness t of the dielectric layer. The outer diameter De of the dielectric layer was measured only for the dielectric layer covering the surface of the CNT. The results are shown in Table 1. It is to be noted that the relative distance means a relative distance based on the length L (100 μm in Example 1) of the VACNT in Table 1.

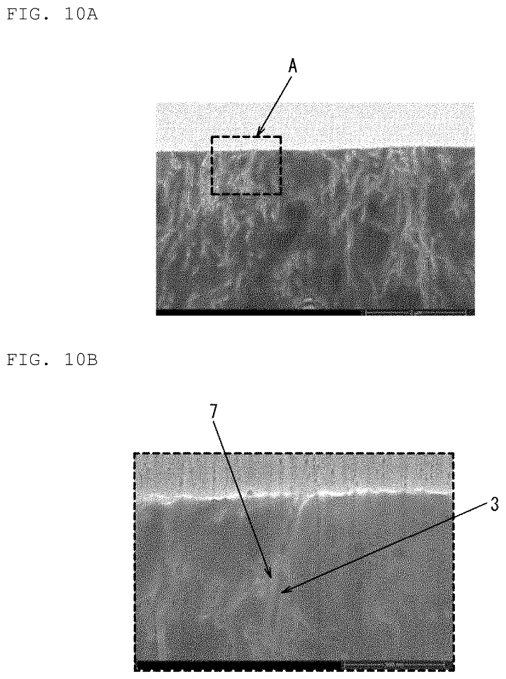

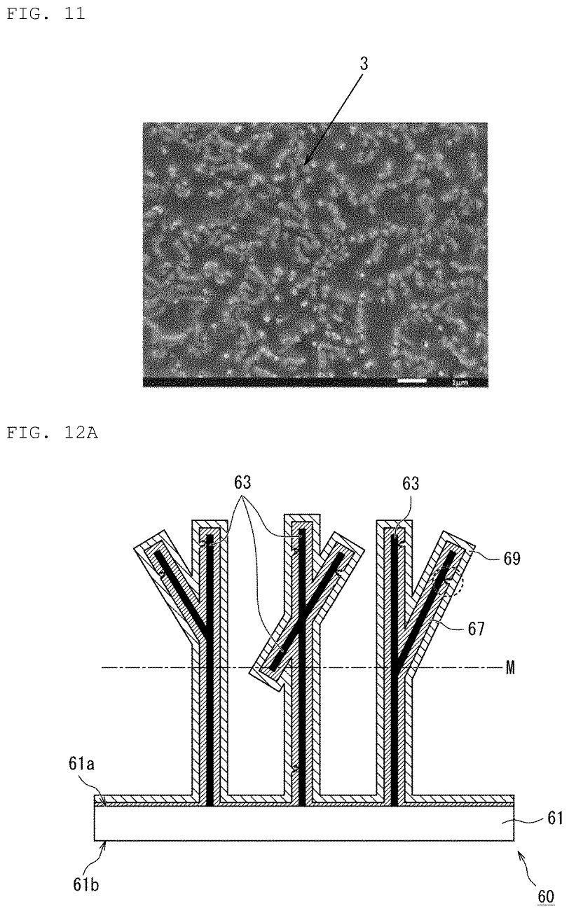

In the sample from which the parallel direction section and the vertical direction section were exposed at the relative distance of 90%, a section parallel to the surface of the Si substrate was further exposed by polishing at a relative distance of 10%, and the CNT number density d at the relative distance of 10% was determined. Furthermore, a section perpendicular to the surface of the Si substrate was exposed by FIB, and the thickness t of the dielectric layer at a relative distance of 10% was then determined. For reference, FIG. 9 shows an example of an SEM image of the parallel direction section obtained by cutting the sample according to Example 1 at the relative distance of 10%, and FIGS. 10A and 10B show an example of an SEM image of the vertical direction section of the sample. FIG. 10B is an enlarged view of a part A in FIG. 10A.

TABLE 1

| | Relative | Dielectric | CNT Number |
|---|---|---|---|
| Distance | Distance | Thickness t | Density d |
| (μm) | (%) | (nm) | (tubes/μm²) |
| 90 | 90 | 55 | 4.1 |
| 10 | 10 | 40 | 3.0 |

When the VACNTs are all considered virtually divided into a proximal half and a distal half with respect to the surface of the Si substrate (when a relative distance of less than 50% is considered as a proximal half, whereas a relative distance of 50% or more is considered as a distal half), it has been confirmed from the results in Table 1 that the distal half of the VACNTs is higher in the number density of the VACNTs and larger in dielectric thickness than the proximal half of the VACNTs.

It can be understood that the capacitor according to Embodiment 1 is fabricated when a conductor layer covering the dielectric layer is formed on such a sample according to Example 1 by any appropriate method.

### Comparative Example 1

A catalyst was applied onto the surface of a Si substrate, and VACNTs were allowed to grow. The length of the VACNTs (the maximum length of CNTs) L was about 1000 μm, and the outer diameter of the CNTs was about 20 nm. For the VACNTs on the Si substrate, a dielectric layer where forty layers of SiO₂ and forty layers of Al₂O₃ were alternately laminated was formed by ALD. Thus, a structure of the VACNTs and dielectric layer (alternate laminate of SiO₂/Al₂O₃) formed on the Si substrate was obtained as a sample according to Comparative Example 1.

For the sample according to Comparative Example 1, the thickness t of the dielectric layer and the CNT number density d were determined in the same manner as in Example 1. The results are shown in Table 2. It is to be noted that the relative distance means a relative distance based on the length L (1000 μm in Comparative Example 1) of the VACNTs in Table 2. For reference, FIG. 11 shows an example of an SEM image of the parallel direction section obtained by cutting the sample according to Comparative Example 1 at the relative distance of 90%.

TABLE 2

| | Relative | Dielectric | CNT Number |
|---|---|---|---|
| Distance | Distance | Thickness t | Density d |
| (μm) | (%) | (nm) | (tubes/μm²) |
| 900 | 90 | 35 | 7.0 |
| 100 | 10 | 40 | 2.8. |

When the VACNTs are all considered virtually divided into a proximal half and a distal half with respect to the surface of the Si substrate (when a relative distance of less than 50% is considered as a proximal half, whereas a relative distance of 50% or more is considered as a distal half), it has been confirmed from the results in Table 2 that the distal half of the VACNTs is higher in the number density of the VACNTs than the proximal half of the VACNTs. In contrast, it has been confirmed that the thickness of the dielectric in the distal half of the VACNTs is slightly smaller than the thickness of the dielectric in the proximal half of the VACNTs. In Comparative Example 1, however, the difference in the thickness of the dielectric layer with respect to the length L of the VACNTs is extremely small, and the thickness of the dielectric is considered substantially uniform regardless of the distance from the surface of the Si substrate.

The capacitor according to the present disclosure can be used in any appropriate application, and particularly, can be suitably used in an application that requires a high capacitance density and a reduction in the number of short circuit paths generated.

### DESCRIPTION OF REFERENCE SYMBOLS

1: Substrate
1a: Surface
1b: Back surface
3, 3′: Plurality of fiber-shaped conductive members
3p: Proximal half (fixed end side half)
3d: Distal half (free end side half)
3p′: Proximal half (free end side half)
3d′: Distal half (fixed end side half)
5: Another conductor layer (underlying conductor layer)
7, 8: Dielectric layer
9, 9′: Conductor layer
11: Adhesive layer
13: Conductor part
20A, 20B, 21A to 21D, 22A, 22B: Capacitor
L: Length of plurality of fiber-shaped conductive members
d: Number density of plurality of fiber-shaped conductive members
t: Thickness of dielectric layer

1. A capacitor comprising:
a substrate with conductivity;
a plurality of fiber-shaped conductive members on the substrate and electrically connected to the substrate;
a dielectric layer covering a surface of the plurality of fiber-shaped conductive members; and
a conductor layer covering a surface of the dielectric layer,
wherein the plurality of fiber-shaped conductive members includes a proximal half present proximally to a surface of the substrate and a distal half present distally to the surface of the substrate, and one of the proximal half and the distal half is higher in number density of the plurality of fiber-shaped conductive members and larger in thickness of the dielectric layer than the other of the proximal half and the distal half.

2. The capacitor according to claim 1, wherein the one of the proximal half and the distal half is the distal half, and the other is the proximal half.

3. The capacitor according to claim 2, wherein the number density of the plurality of fiber-shaped conductive members and the thickness of the dielectric layer at a distance of 75% of a length of the plurality of fiber-shaped conductive members from the surface of the substrate are respectively larger than the number density of the plurality of fiber-shaped conductive members and the thickness of the dielectric layer at a distance of 25% of the length of the plurality of fiber-shaped conductive members from the surface of the substrate.

4. The capacitor according to claim 2, wherein the number density of the plurality of fiber-shaped conductive members and the thickness of the dielectric layer at a distance of 90% of a length of the plurality of fiber-shaped conductive members from the surface of the substrate are respectively larger than the number density of the plurality of fiber-shaped conductive members and the thickness of the dielectric layer at a distance of 10% of the length of the plurality of fiber-shaped conductive members from the surface of the substrate.

5. The capacitor according to claim 1, wherein the one of the proximal half and the distal half is the proximal half, and the other is the distal half.

6. The capacitor according to claim 5, wherein the number density of the plurality of fiber-shaped conductive members and the thickness of the dielectric layer at a distance of 25% of a length of the plurality of fiber-shaped conductive members from the surface of the substrate are respectively larger than the number density of the plurality of fiber-shaped conductive members and the thickness of the dielectric layer at a distance of 75% of the length of the plurality of fiber-shaped conductive members from the surface of the substrate.

7. The capacitor according to claim 5, wherein the number density of the plurality of fiber-shaped conductive members and the thickness of the dielectric layer at a distance of 10% of a length of the plurality of fiber-shaped conductive members from the surface of the substrate are respectively larger than the number density of the plurality of fiber-shaped conductive members and the thickness of the dielectric layer at a distance of 90% of the length of the plurality of fiber-shaped conductive members from the surface of the substrate.

8. The capacitor according to claim 1, wherein the plurality of fiber-shaped conductive members are directly bonded to the substrate.

9. The capacitor according to claim 1, wherein the plurality of fiber-shaped conductive members are bonded to the substrate with an adhesive layer.

10. The capacitor according to claim 1, wherein one of the proximal half and the distal half has more surface defects at the plurality of fiber-shaped conductive members than the other.

11. The capacitor according to claim 1, wherein each of the plurality of the fiber-shaped conductive members is a carbon nanotube.

12. The capacitor according to claim 1, wherein the conductor layer includes a conductive polymer.

13. The capacitor according to claim 1, wherein the conductor layer is a first conductor layer and the capacitor further comprises a second conductor layer between the surface of the plurality of fiber-shaped conductive members and the dielectric layer.

14. The capacitor according to claim 1, further comprising a conductor part in contact with and electrically connected to the conductor layer, and not in contact with the dielectric layer, the fiber-shaped conductive members, or the substrate.

15. A method for manufacturing a capacitor, the method comprising:
(a) joining a first end of a plurality of fiber-shaped conductive members to a surface of a first substrate, wherein the plurality of fiber-shaped conductive members include a fixed end side half that is present proximally to the surface of the first substrate and a free end side half that is present distally to the surface of the first substrate, and the free end side half is higher in number density of the plurality of fiber-shaped conductive members than the fixed end side half;
(b) covering a surface of the plurality of fiber-shaped conductive members with a first dielectric layer by a liquid phase film formation method or a sputtering method, wherein the free end side half is larger in thickness of the first dielectric layer than the fixed end side half; and
(c) covering a surface of the first dielectric layer with a conductor layer.

16. The method for manufacturing a capacitor according to claim 15, wherein the joining of the first end of the plurality of fiber-shaped conductive members is performed by applying a catalyst onto the first substrate and allowing the plurality of fiber-shaped conductive members to grow from the first substrate.

17. The method for manufacturing a capacitor according to claim 15, wherein the first substrate has conductivity, and
a capacitor including the plurality of fiber-shaped conductive members disposed on the first substrate and electrically connected to the first substrate, the dielectric layer, and the conductor layer is obtained through the covering of the surface of the first dielectric layer with the conductor layer.

18. The method for manufacturing a capacitor according to claim 15, further including after the (b) and before the (c):
(d) exposing, from the dielectric layer, the plurality of fiber-shaped conductive members at free end parts opposite to the first substrate, bringing the free end parts of the plurality of fiber-shaped conductive members into contact with an adhesive layer located on a second substrate with conductivity to transfer the plurality of fiber-shaped conductive members to the second substrate, removing the first substrate from the plurality of fiber-shaped conductive members, and then covering with a second dielectric layer parts of the plurality of fiber-shaped conductive members exposed by removing the first substrate,
wherein a capacitor including the plurality of fiber-shaped conductive members disposed on the second substrate and electrically connected to the second substrate, the dielectric layer, and the conductor layer is obtained by the covering of the surface of the first and second dielectric layers with the conductor layer.
